(19) United States
(12) Patent Application Publication
(10) Pub. No.: US 2009/0185411 A1
(43) Pub. Date: Jul. 23, 2009

(54) INTEGRATED CIRCUIT INCLUDING DIODE MEMORY CELLS

(76) Inventors: Thomas Happ, Dresden (DE); Chung Hon Lam, Peekskill, NY (US); Hsiang-Lan Lung, Elmsford, NY (US); Bipin Rajendran, White Plains, NY (US); Min Yang, Yorktown Heights, NY (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 12/017,581

(22) Filed: Jan. 22, 2008

(51) Int. Cl. G11C 11/00; H01L 21/06

(52) U.S. Cl. 365/163; 365/148; 438/102; 257/E21.068

(57) ABSTRACT

The integrated circuit includes a first metal line and a first diode coupled to the first metal line. The integrated circuit includes a first resistivity changing material coupled to the first diode and a second metal line coupled to the first resistivity changing material.

### BACKGROUND

One type of memory is resistive memory. Resistive memory utilizes the resistance value of a memory element to store one or more bits of data. For example, a memory element programmed to have a high resistance value may represent a logic “1” data bit value and a memory element programmed to have a low resistance value may represent a logic “0” data bit value. Typically, the resistance value of the memory element is switched electrically by applying a voltage pulse or a current pulse to the memory element.

One type of resistive memory is phase change memory. Phase change memory uses a phase change material in the resistive memory element. The phase change material exhibits at least two different states. The states of the phase change material may be referred to as the amorphous state and the crystalline state, where the amorphous state involves a more disordered atomic structure and the crystalline state involves a more ordered lattice. The amorphous state usually exhibits higher resistivity than the crystalline state. Also, some phase change materials exhibit multiple crystalline states, e.g. a face-centered cubic (FCC) state and a hexagonal closest packing (HCP) state, which have different resistivities and may be used to store bits of data. In the following description, the amorphous state generally refers to the state having the higher resistivity and the crystalline state generally refers to the state having the lower resistivity.

Phase changes in the phase change materials may be induced reversibly. In this way, the memory may change from the amorphous state to the crystalline state and from the crystalline state to the amorphous state in response to temperature changes. The temperature changes of the phase change material may be achieved by driving current through the phase change material itself or by driving current through a resistive heater adjacent the phase change material. With both of these methods, controllable heating of the phase change material causes controllable phase change within the phase change material.

A phase change memory including a memory array having a plurality of memory cells that are made of phase change material may be programmed to store data utilizing the memory states of the phase change material. One way to read and write data in such a phase change memory device is to control a current and/or a voltage pulse that is applied to the phase change material. The temperature in the phase change material in each memory cell generally corresponds to the applied level of current and/or voltage to achieve the heating.

To achieve higher density phase change memories, a phase change memory cell can store multiple bits of data. Multi-bit storage in a phase change memory cell can be achieved by programming the phase change material to have intermediate resistance values or states, where the multi-bit or multilevel phase change memory cell can be written to more than two states. If the phase change memory cell is programmed to one of three different resistance levels, 1.5 bits of data per cell can be stored. If the phase change memory cell is programmed to one of four different resistance levels, two bits of data per cell can be stored, and so on. To program a phase change memory cell to an intermediate resistance value, the amount of crystalline material coexisting with amorphous material and hence the cell resistance is controlled via a suitable write strategy.

Higher density phase change memories can also be achieved by reducing the physical size of each memory cell. Increasing the density of a phase change memory increases the amount of data that can be stored within the memory while at the same time typically reducing the cost of the memory.

For these and other reasons, there is a need for the present invention.

### SUMMARY

One embodiment provides an integrated circuit. The integrated circuit includes a first metal line and a first diode coupled to the first metal line. The integrated circuit includes a first resistivity changing material coupled to the first diode and a second metal line coupled to the first resistivity changing material.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a system.

FIG. 2 is a diagram illustrating one embodiment of a memory device.

FIG. 3 illustrates a cross-sectional view of one embodiment of a three dimensional array of diode memory cells.

FIG. 4 illustrates a cross-sectional view of one embodiment of array logic and a first word line.

FIG. 5 illustrates a cross-sectional view of one embodiment of the first word line, a silicon plug, a first dielectric material layer, and a second dielectric material layer.

FIG. 6 illustrates a cross-sectional view of one embodiment of the first word line, a recessed silicon plug, the first dielectric material layer, and the second dielectric material layer.

FIG. 7 illustrates a cross-sectional view of one embodiment of the first word line, a diode, a silicide contact, the first dielectric material layer, and the second dielectric material layer.

FIG. 8 illustrates a cross-sectional view of one embodiment of the first word line, the diode, the silicide contact, the first dielectric material layer, and the second dielectric material layer after undercut etching the first dielectric material layer.

FIG. 9 illustrates a cross-sectional view of one embodiment of the first word line, the diode, the silicide contact, the first dielectric material layer, and a third dielectric material layer.

FIG. 10 illustrates a cross-sectional view of one embodiment of the first word line, the diode, the silicide contact, the first dielectric material layer, the third dielectric material layer, and a keyhole formed in a conformal layer.

FIG. 11 illustrates a cross-sectional view of one embodiment of the first word line, the diode, the silicide contact, the first dielectric material layer, the third dielectric material layer, and a layer after etching the conformal layer.

FIG. 12 illustrates a cross-sectional view of one embodiment of the first word line, the diode, the silicide contact, the first dielectric material layer, dielectric material, and the layer after etching the third dielectric material layer.

FIG. 13 illustrates a cross-sectional view of one embodiment of the first word line, the diode, the silicide contact, the first dielectric material layer, and the dielectric material after removing the layer.

FIG. 14 illustrates a cross-sectional view of one embodiment of the first word line, the diode, the silicide contact, the first dielectric material layer, the dielectric material, a phase change material storage location, and a top electrode.

FIG. 15 illustrates a cross-sectional view of one embodiment of the first word line, the diode, the silicide contact, the first dielectric material layer, the dielectric material, the phase change material storage location, the top electrode, and a cap material layer.

FIG. 16 illustrates a cross-sectional view of one embodiment of the array of diode phase change memory cells after fabricating vias.

FIG. 17 illustrates a cross-sectional view of one embodiment of the array of diode phase change memory cells after fabricating bit lines and contacts.

FIG. 18 illustrates a cross-sectional view of another embodiment of an array of diode phase change memory cells.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

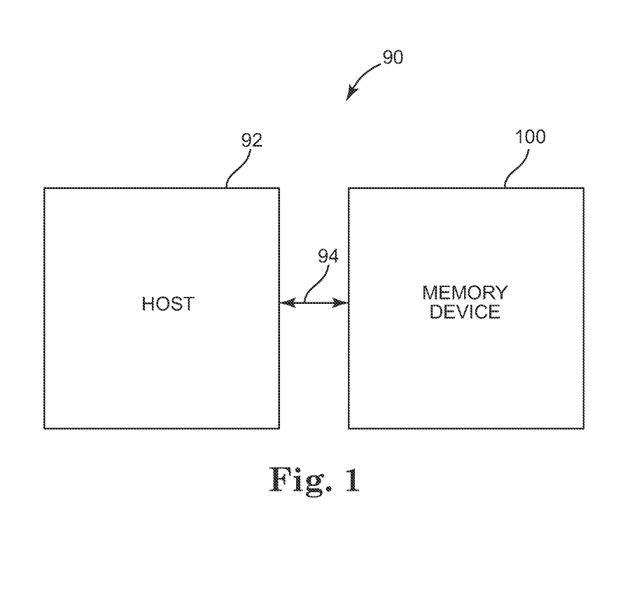

FIG. 1 is a block diagram illustrating one embodiment of a system 90. System 90 includes a host 92 and a memory device 100. Host 92 is communicatively coupled to memory device 100 through communication link 94. Host 92 includes a computer (e.g., desktop, laptop, handheld), portable electronic device (e.g., cellular phone, personal digital assistant (PDA), MP3 player, video player, digital camera), or any other suitable device that uses memory. Memory device 100 provides memory for host 92. In one embodiment, memory device 100 includes a phase change memory device or other suitable resistive or resistivity changing material memory device.

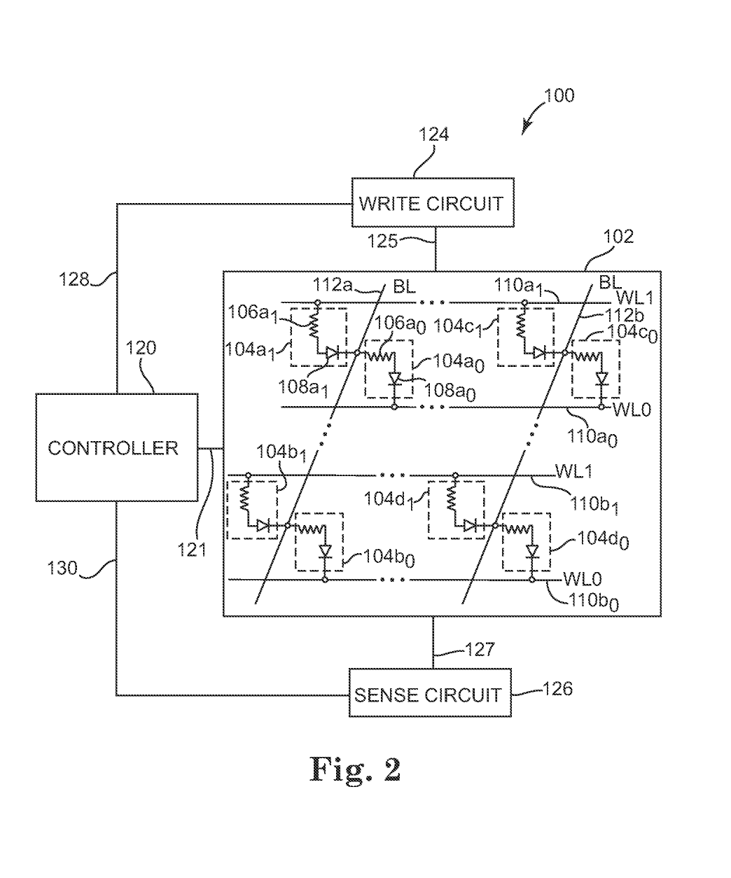

FIG. 2 is a diagram illustrating one embodiment of memory device 100. In one embodiment, memory device 100 is an integrated circuit or part of an integrated circuit. Memory device 100 includes a write circuit 124, a controller 120, a memory array 102, and a sense circuit 126. Memory array 102 includes a plurality of diode resistive memory cells 104a₀₋₁-104d₀₋₁ (collectively referred to as diode resistive memory cells 104), a plurality of bit lines (BLs) 112a-112b (collectively referred to as bit lines 112), and a plurality of word lines (WLs) 110a₀₋₁-110b₀₋₁ (collectively referred to as word lines 110). In one embodiment, diode resistive memory cells 104 are diode phase change memory cells. In other embodiments, diode resistive memory cells 104 are another suitable type of diode resistive memory cells or resistivity changing material memory cells.

Memory array 102 includes a three dimensional array of diode phase change memory cells 104. In one embodiment, memory array 102 includes two layers of diode phase change memory cells 104. In other embodiments, memory array 102 includes any suitable number, such as 3, 4, or more layers of diode phase change memory cells 104. Word lines 110 and bit lines 112 are made of metal, which reduces the resistivity of the lines.

As used herein, the term “electrically coupled” is not meant to mean that the elements must be directly coupled together and intervening elements may be provided between the “electrically coupled” elements.

Memory array 102 is electrically coupled to write circuit 124 through signal path 125, to controller 120 through signal path 121, and to sense circuit 126 through signal path 127. Controller 120 is electrically coupled to write circuit 124 through signal path 128 and to sense circuit 126 through signal path 130.

Each diode phase change memory cell 104 is electrically coupled to a word line 110 and a bit line 112. Diode phase change memory cell 104a₀ is electrically coupled to bit line 112a and word line 110a₀, and diode phase change memory cell 104a₁ is electrically coupled to bit line 112a and word line 110a₁. Diode phase change memory cell 104b₀ is electrically coupled to bit line 112a and word line 110b₀, and diode phase change memory cell 104b₁ is electrically coupled to bit line 112a and word line 110b₁. Diode phase change memory cell 104c₀ is electrically coupled to bit line 112b and word line 110a₀, and diode phase change memory cell 104c₁ is electrically coupled to bit line 112b and word line 110a₁. Diode phase change memory cell 104d₀ is electrically coupled to bit line 112b and word line 110b₀, and diode phase change memory cell 104d₁ is electrically coupled to bit line 112b and word line 110b₁.

Each diode phase change memory cell 104 includes a phase change element 106 and a diode 108. In one embodiment, the polarity of diodes 108 is reversed. For example, diode phase change memory cell 104a₀ includes phase change element 106a₀ and diode 108a₀. One side of phase change element 106a₀ is electrically coupled to bit line 112a, and the other side of phase change element 106a₀ is electrically coupled to one side of diode 108a₀. The other side of diode 108a₀ is electrically coupled to word line 110a₀. Diode phase change memory cell 104a₁ includes phase change element 106a₁ and diode 108a₁. One side of phase change element 106a₁ is electrically coupled to word line 110a₁, and the other side of phase change element 106a₁ is electrically coupled to one side of diode 108a₁. The other side of diode 108a₁ is electrically coupled to bit line 112a.

In another embodiment, the location of each phase change element 106 and each diode 108 is reversed. For example, for diode phase change memory cell 104a₀, one side of phase change element 106a₀ is electrically coupled to word line 110a₀. The other side of phase change element 106a₀ is electrically coupled to one side of diode 108a₀. The other side of diode 108a₀ is electrically coupled to bit line 112a. For diode phase change memory cell 104a₁, one side of phase change element 106a₁ is electrically coupled to bit line 112a. The other side of phase change element 106a₁ is electrically coupled to one side of diode 108a₁. The other side of diode 108a₁ is electrically coupled to word line 110a₁.

In one embodiment, each phase change element 106 includes a phase change material that may be made up of a variety of materials in accordance with the present invention. Generally, chalcogenide alloys that contain one or more elements from Group VI of the periodic table are useful as such materials.

In one embodiment, the phase change material is made up of a chalcogenide compound material, such as GeSbTe, SbTe, GeTe, or AgInSbTe. In another embodiment, the phase change material is chalcogen free, such as GeSb, GaSb, InSb, or GeGaInSb. In other embodiments, the phase change material is made up of any suitable material including one or more of the elements Ge, Sb, Te, Ga, As, In, Se, and S.

Each phase change element 106 may be changed from an amorphous state to a crystalline state or from a crystalline state to an amorphous state under the influence of temperature change. The amount of crystalline material coexisting with amorphous material in the phase change material of one of the phase change elements 106 thereby defines two or more states for storing data within memory device 100. In the amorphous state, a phase change material exhibits significantly higher resistivity than in the crystalline state. Therefore, the two or more states of the phase change elements differ in their electrical resistivity. In one embodiment, the two or more states are two states and a binary system is used, wherein the two states are assigned bit values of “0” and “1”. In another embodiment, the two or more states are three states and a ternary system is used, wherein the three states are assigned bit values of “0”, “1”, and “2”. In another embodiment, the two or more states are four states that are assigned multi-bit values, such as “00”, “01”, “10”, and “11”. In other embodiments, the two or more states can be any suitable number of states in the phase change material of a phase change element.

Controller 120 includes a microprocessor, microcontroller, or other suitable logic circuitry for controlling the operation of memory device 100. Controller 120 controls read and write operations of memory device 100 including the application of control and data signals to memory array 102 through write circuit 124 and sense circuit 126. In one embodiment, write circuit 124 provides voltage pulses through signal path 125 and bit lines 112 to memory cells 104 to program the memory cells. In other embodiments, write circuit 124 provides current pulses through signal path 125 and bit lines 112 to memory cells 104 to program the memory cells.

Sense circuit 126 reads each of the two or more states of memory cells 104 through bit lines 112 and signal path 127. In one embodiment, to read the resistance of one of the memory cells 104, sense circuit 126 provides current that flows through one of the memory cells 104. Sense circuit 126 then reads the voltage across that one of the memory cells 104. In another embodiment, sense circuit 126 provides voltage across one of the memory cells 104 and reads the current that flows through that one of the memory cells 104. In another embodiment, write circuit 124 provides voltage across one of the memory cells 104 and sense circuit 126 reads the current that flows through that one of the memory cells 104. In another embodiment, write circuit 124 provides current that flows through one of the memory cells 104 and sense circuit 126 reads the voltage across that one of the memory cells 104.

In one embodiment, during a “set” operation of diode phase change memory cell 104a₀, word line 110a₀ is selected. With word line 110a₀ selected, a set current or voltage pulse is selectively enabled by write circuit 124 and sent through bit line 112a to phase change element 106a₀ thereby heating phase change element 106a₀ above its crystallization temperature (but usually below its melting temperature). In this way, phase change element 106a₀ reaches the crystalline state or a partially crystalline and partially amorphous state during this set operation.

During a “reset” operation of diode phase change memory cell 104a₀, word line 110a₀ is selected. With word line 110a₀ selected, a reset current or voltage pulse is selectively enabled by write circuit 124 and sent through bit line 112a to phase change element 106a₀. The reset current or voltage quickly heats phase change element 106a₀ above its melting temperature. After the current or voltage pulse is turned off, phase change element 106a₀ quickly quench cools into the amorphous state or a partially amorphous and partially crystalline state.

Diode phase change memory cells 104a₁, 104b₀₋₁-104d₀₋₁, and other diode phase change memory cells 104 in memory array 102 are set and reset similarly to diode phase change memory cell 104a₀ using a similar current or voltage pulse applied through the appropriate bit line 112 and word line 110. In other embodiments, for other types of resistive memory cells, write circuit 124 provides suitable programming pulses to program the resistive memory cells 104 to the desired state.

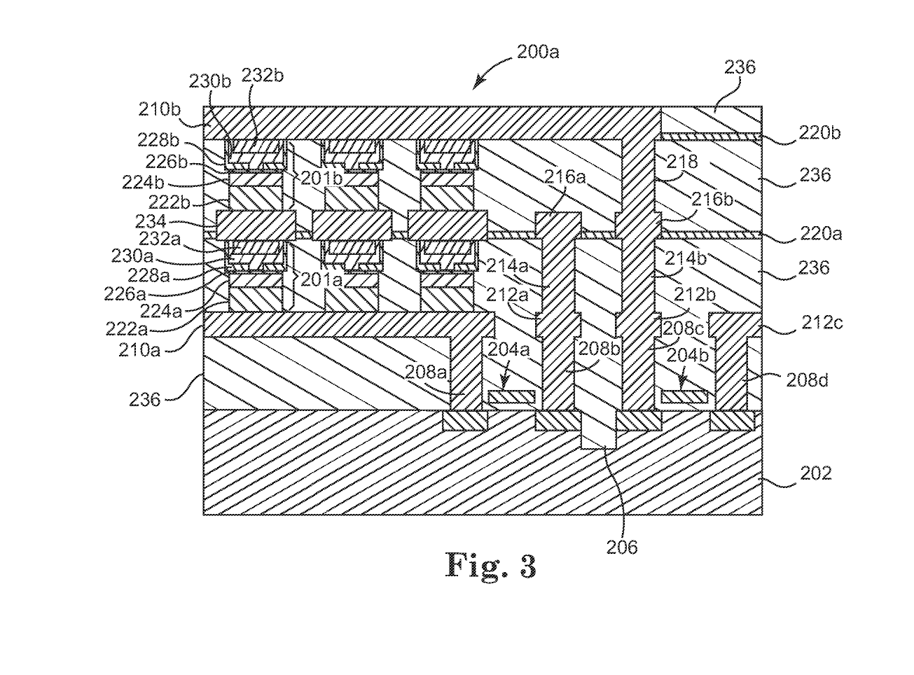

FIG. 3 illustrates a cross-sectional view of one embodiment of a three dimensional array 200a of diode memory cells. In one embodiment, three dimensional array 200a provides memory array 102. Three dimensional array 200a includes a substrate 202, shallow trench isolation (STI) 206 or other suitable isolation, transistors 204a and 204b, contacts 208a-208d, 212a-212c, 216a, and 216b, vias 214a, 214b, and 218, and dielectric material 236, 220a, and 220b. Three dimensional array 200a also includes a first word line 210a, first diode phase change memory cells such as indicated at 201a, bit lines such as indicated at 234, second diode phase change memory cells such as indicated at 201b, and a second word line 210b.

Each first diode phase change memory cell 201a includes an N+/N− region 222a, a P+ region 224a, a silicide contact 226a, dielectric material 228a, a phase change material storage location 230a, and a top electrode 232a. N+/N− region 222a and P+ region 224a form a diode 108. In another embodiment, the polarity of diode 108 and the associated dopings are reversed. Each second diode phase change memory cell 201b includes an N+/N− region 222b, a P+ region 224b, a silicide contact 226b, dielectric material 228b, a phase change material storage location 230b, and a top electrode 232b. N+/N− region 222b and P+ region 224b form a diode 108. In another embodiment, the polarity of diode 108 and the associated dopings are reversed.

Transistors 204a and 204b are formed in substrate 202. Substrate 202 includes a silicon substrate or another suitable substrate. STI 206 electrically isolates adjacent transistors from each other. One side of the source/drain path of transistor 204a contacts the bottom of contact 208a. The other side of the source/drain path of transistor 204a contacts the bottom of contact 208b. The top of contact 208a contacts the bottom of first word line 210a. The top of contact 208b contacts the bottom of contact 212a. The top of contact 212a contacts the bottom of via 214a. The top of via 214a contacts the bottom of contact 216a. Contact 216a is electrically coupled to a master word line (not shown), which is electrically coupled to first word line 210a by activating transistor 204a.

One side of the source/drain path of transistor 204b contacts the bottom of contact 208c. The other side of the source/drain path of transistor 204b contacts the bottom of contact 208d. The top of contact 208c contacts the bottom of contact 212b. The top of contact 212b contacts the bottom of via 214b. The top of via 214b contacts the bottom of contact 216b. The top of contact 216b contacts the bottom of via 218. The top of via 218 contacts the bottom of second word line 210b. The top of contact 208d contacts the bottom of contact 212c. Contact 212c is electrically coupled to a master word line (not shown), which is electrically coupled to second word line 210b by activating transistor 204b.

Contacts 208a-208d, 212a-212c, 216a, and 216b, vias 214a, 214b, and 218, word lines 210a and 210b, and bit lines 234 include W, Al, Cu, or another suitable material. Contacts 208a-208d, 212a-212c, 216a, and 216b, vias 214a, 214b, and 218, word lines 210a and 210b, and bit line 234 are laterally surrounded by dielectric material 236. Dielectric material 236 includes SiO₂, SiOₓ, SiN, fluorinated silica glass (FSG), boro-phosphorous silicate glass (BPSG), boro-silicate glass (BSG), or another suitable dielectric material.

A portion of the top of first word line 210a contacts the bottom of each N+/N− region 222a. In one embodiment, each N+/N− region 222a includes doped polysilicon or doped single crystal silicon. The top of each N+/N− region 222a contacts the bottom of a P+ region 224a. In one embodiment, each P+ region 224a includes doped polysilicon or doped single crystal silicon. The top of each P+ region 224a contacts the bottom of a silicide contact 226a. Each silicide contact 226a includes CoSi, TiSi, NiSi, TaSi, or another suitable silicide.

The top of each silicide contact 226a contacts the bottom of dielectric material 228a and a portion of the bottom of a phase change material storage location 230a. Dielectric material 228a includes SiN, SiO₂, SiOₓN, TaOs, Al₂O₃, or another suitable dielectric material. Dielectric material 228a laterally encloses each phase change material storage location 230a. Each phase change material storage location 230a provides a storage location for storing one or more bits of data. The active or phase change region of each phase change material storage location 230a is at or close to the interface between phase change material storage location 230a and silicide contact 226a. In one embodiment, the interface between phase change material storage location 230a and silicide contact 226a has a sublithographic cross-section.

Each phase change material storage location 230a contacts the bottom and sidewalls of a top electrode 232a. Each top electrode 232a includes TiN, TaN, W, WN, Al, C, Ti, Ta, TiSiN, TaSiN, TiAlN, TaAlN, Cu, or another suitable electrode material. Each first diode phase change memory cell 201a is laterally surrounded by dielectric material 236.

The top of each top electrode 232a contacts the bottom of a bit line 234. The top of each bit line 234 contacts the bottom of a second diode phase change memory cell 201b. The elements of each second diode phase change memory cell 201b, including 222b, 224b, 226b, 228b, 230b, and 232b, are similar to and configured similarly to the corresponding elements previously described for each first diode phase change memory cell 201a. The top of each second diode phase change memory cell 201b contacts the bottom of second word line 210b. Any suitable number of additional word lines and diode phase change memory cells can be provided above word line 210b.

The current path through each first diode phase change memory cell 201a is from a bit line 234 through a top electrode 232a and a phase change material storage location 230a to a silicide contact 226a. From silicide contact 226a, the current flows through the diode formed by P+ region 224a and N+/N− region 222a. From N+/N− region 222a, the current flows through first word line 210a and transistor 204a to contact 216a. The cross-sectional width of the interface area between each phase change material storage location 230a and silicide contact 226a defines the current density through the interface and thus the power used to program each memory cell 201a. By reducing the cross-sectional width of the interface area, the current density is increased, thus reducing the power used to program each memory cell 201a.

During operation of a memory cell 201a, current or voltage pulses are applied between a bit line 234 and first word line 210a to program a selected memory cell 201a. During a set operation of a selected memory cell 201a, a set current or voltage pulse is selectively enabled by write circuit 124 and sent through a bit line 234 to a top electrode 232a. From top electrode 232a, the set current or voltage pulse passes through a phase change material storage location 230a thereby heating the phase change material above its crystallization temperature (but usually below its melting temperature). In this way, the phase change material reaches a crystalline state or a partially crystalline and partially amorphous state during the set operation.

During a reset operation of a selected memory cell 201a, a reset current or voltage pulse is selectively enabled by write circuit 124 and sent through a bit line 234 to a top electrode 232a. From top electrode 232a, the reset current or voltage pulse passes through a phase change material storage location 230a. The reset current or voltage quickly heats the phase change material above its melting temperature. After the current or voltage pulse is turned off, the phase change material quickly quench cools into an amorphous state or a partially amorphous and partially crystalline state.

The current path through each second diode phase change memory cell 201b is from second word line 210b through a top electrode 232b and a phase change material storage location 230b to a silicide contact 226b. From silicide contact 226b, the current flows through the diode formed by P+ region 224b and N+/N− region 222b. From N+/N− region 222b the current flows to a bit line 234. Each second diode phase change memory cell 201b is programmed similarly to each first diode phase change memory cell 201a.

The following FIGS. 4-17 illustrate embodiments for fabricating a three dimensional array of diode phase change memory cells, such as three dimensional array 200a previously described and illustrated with reference to FIG. 3.

FIG. 4 illustrates a cross-sectional view of one embodiment of array logic 238 and a first word line 210a. Array logic 238 includes transistors 204a and 204b. Transistors 204a and 204b are formed in substrate 202. Substrate 202 includes a silicon substrate or another suitable substrate. STI 206 is provided between adjacent transistors to electrically isolate the transistors from each other. The gates of transistors 204a and 204b are electrically coupled to control lines for activating transistors 204a and 204b. Contacts 208a-208d each contact a source/drain region of transistors 204a and 204b. Contacts 208a-208d include W, Al, Cu, or another suitable metal. Dielectric material laterally encloses contacts 208a-208d. The dielectric material includes SiO₂, SiOₓ, SiN, FSG, BPSG, BSG, or another suitable dielectric material.

A metal, such as W, Al, Cu, or another suitable metal is deposited over the dielectric material and contacts 208a-208d to provide a metal layer. The metal layer is deposited using chemical vapor deposition (CVD), high density plasma-chemical vapor deposition (HDP-CVD), atomic layer deposition (ALD), metal organic chemical vapor deposition (MOCVD), physical vapor deposition (PVD), jet vapor deposition (JVD), or other suitable deposition technique. The metal is then etched to expose portions of the dielectric material to provide first word line 210a and contacts 212a-212c.

Dielectric material, such as SiO₂, SiOₓ, SiN, FSG, BPSG, BSG, or another suitable dielectric material is deposited over first word line 210a and contacts 212a-212c. The dielectric material is deposited using CVD, HDP-CVD, ALD, MOCVD, PVD, JVD, or other suitable deposition technique. The dielectric material is then planarized using CMP or another suitable planarization technique to expose first word line 210a and contacts 212a-212c and to provide dielectric material 236a.

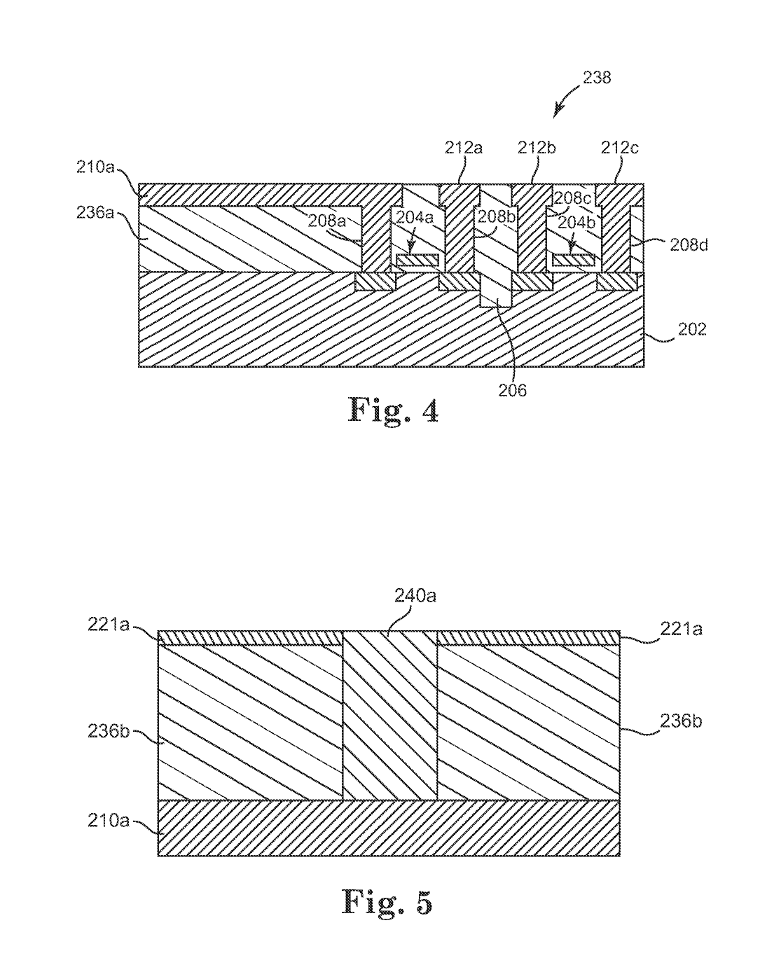

FIG. 5 illustrates a cross-sectional view of one embodiment of first word line 210a, a silicon plug 240a, a first dielectric material layer 236b, and a second dielectric material layer 221a. A first dielectric material, such as SiO₂, SiOₓ, SiN, FSG, BPSG, BSG, or another suitable dielectric material is deposited over first word line 210a to provide a first dielectric material layer. The first dielectric material layer is deposited using CVD, HDP-CVD, ALD, MOCVD, PVD, JVD, spin on or another suitable deposition technique.

A second dielectric material, such as SiN or another suitable dielectric material is deposited over the first dielectric material layer to provide a second dielectric material layer. The second dielectric material layer is deposited using CVD, HDP-CVD, ALD, MOCVD, PVD, JVD, or other suitable deposition technique. The second dielectric material layer and the first dielectric material layer are then etched to provide an opening exposing a portion of first word line 210a and to provide first dielectric material layer 236b and second dielectric material layer 221a. In one embodiment, the opening is cylindrical in shape. In other embodiments, the opening has another suitable shape.

Silicon is then deposited into the opening or an epitaxy process is used to provide silicon plug 240a. In one embodiment, silicon plug 240a comprises polysilicon. In one embodiment, silicon plug 240a is obtained through a chemical vapor deposition process with a deposition temperature in the range of 600° C. to 800° C. and a silane gas flow rate in the range of 100 to 500 sccm at pressures less than 500 mTorr. In another embodiment, the silicon plug comprises crystalline silicon obtained through a solid state epitaxy process.

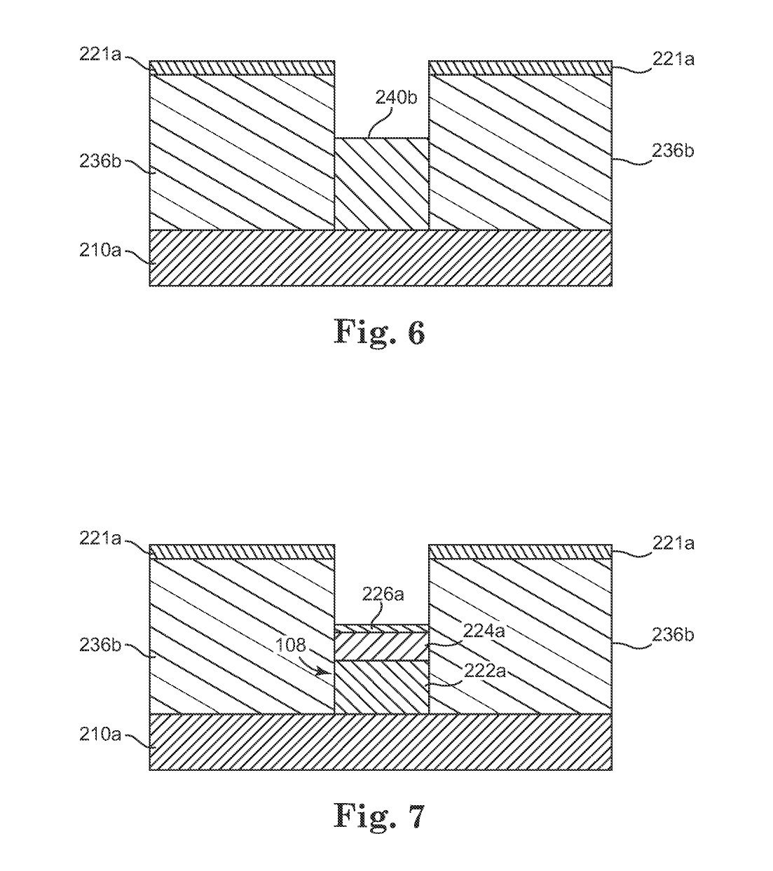

FIG. 6 illustrates a cross-sectional view of one embodiment of first word line 210a, a recessed silicon plug 240b, first dielectric material layer 236b, and second dielectric material layer 221a. Silicon plug 240a is etched back to provide recessed silicon plug 240b.

FIG. 7 illustrates a cross-sectional view of one embodiment of first word line 210a, a diode 108, a silicide contact 226a, first dielectric material layer 236b, and second dielectric material layer 221a. In one embodiment, a protective dielectric material (not shown), such as SiO₂ or another suitable dielectric material is deposited over exposed portions of second dielectric material layer 221a, first dielectric material layer 236b, and recessed silicon plug 240b to provide a protective dielectric material layer. Recessed silicon plug 240b is then implanted with suitable dopants to provide N+/N− region 222a and P+ region 224a. In other embodiments, other suitable processes are used to provide N+/N− region 222a and P+ region 224a, such as deposition of doped polysilicon. In any case, N+/N− region 222a and P+ region 224a are annealed to form silicide contact 226a. N+/N− region 222a and P+ region 224a provide diode 108. In one embodiment, the polarity of the diode is reversed. In one embodiment, the protective dielectric material layer is then removed.

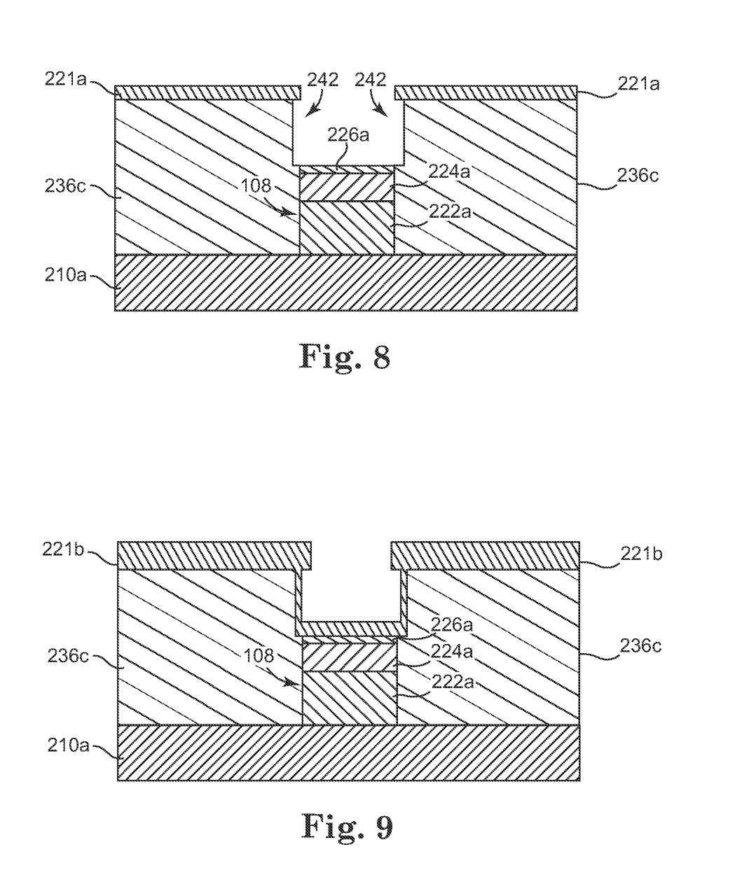

FIG. 8 illustrates a cross-sectional view of one embodiment of first word line 210a, diode 108, silicide contact 226a, first dielectric material layer 236c, and second dielectric material layer 221a after undercut etching first dielectric material layer 236b. First dielectric material layer 236b is selectively recess etched using a selective wet etch or another suitable etch to create an overhang of second dielectric material layer 221a as indicated at 242 and to provide first dielectric material layer 236c.

FIG. 9 illustrates a cross-sectional view of one embodiment of first word line 210a, diode 108, silicide contact 226a, first dielectric material layer 236c, and a third dielectric material layer 221b. A dielectric material, such as SiN or another suitable dielectric material is deposited over exposed portions of second dielectric material layer 221a, first dielectric material layer 236c, and silicide contact 226a to provide a third dielectric material layer 221b. Third dielectric material layer 221b includes second dielectric material layer 221a. The dielectric material layer is deposited using CVD, HDP-CVD, ALD, MOCVD, PVD, JVD, or other suitable deposition technique.

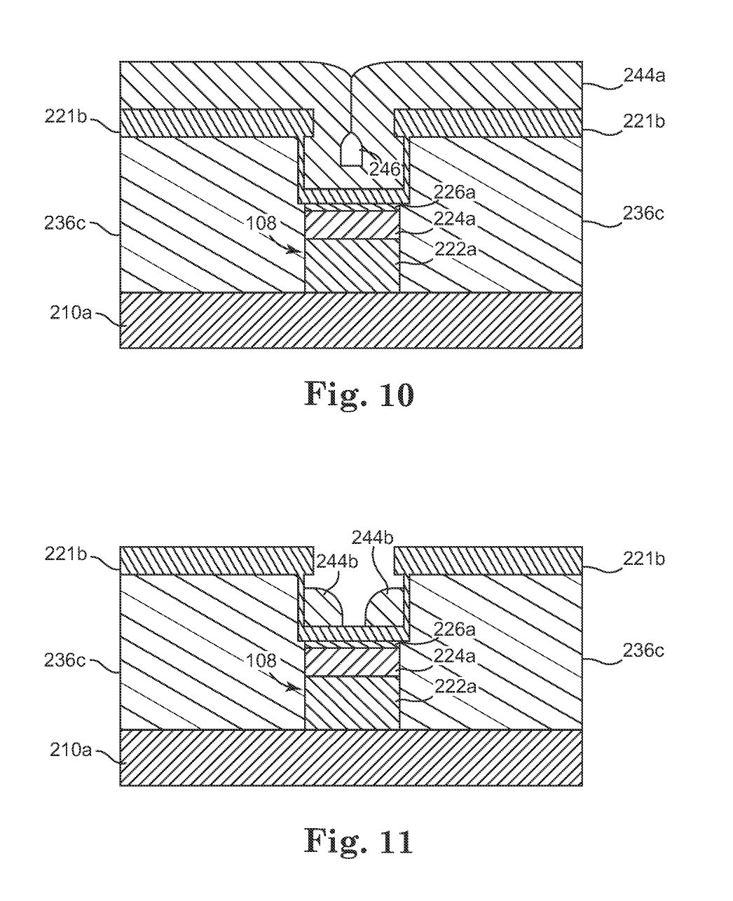

FIG. 10 illustrates a cross-sectional view of one embodiment of first word line 210a, diode 108, silicide contact 226a, first dielectric material layer 236c, third dielectric material layer 221b, and a keyhole 246 formed in a conformal layer 244a. Polysilicon or another suitable material is conformally deposited over exposed portions of third dielectric material layer 221b to provide conformal layer 244a. In other embodiments, conformal layer 244a is a dielectric material, such as SiO₂, or a semiconductor material, such as amorphous silicon. Due to overhang 242, conformal layer 244a pinches itself off forming a void or keyhole 246. Keyhole 246 is substantially centered over silicide contact 226a. Conformal layer 244a is deposited using CVD, HDP-CVD, ALD, MOCVD, PVD, JVD, or other suitable deposition technique.

FIG. 11 illustrates a cross-sectional view of one embodiment of first word line 210a, diode 108, silicide contact 226a, first dielectric material layer 236c, third dielectric material layer 221b, and the layer 244b after etching conformal layer 244a. Conformal layer 244a is spacer etched to provide the layer 244b exposing a portion of third dielectric material layer 221b. The exposed portion of third dielectric material layer 221b over silicide contact 226a has a sublithographic cross-section substantially equal to the cross-section of keyhole 246.

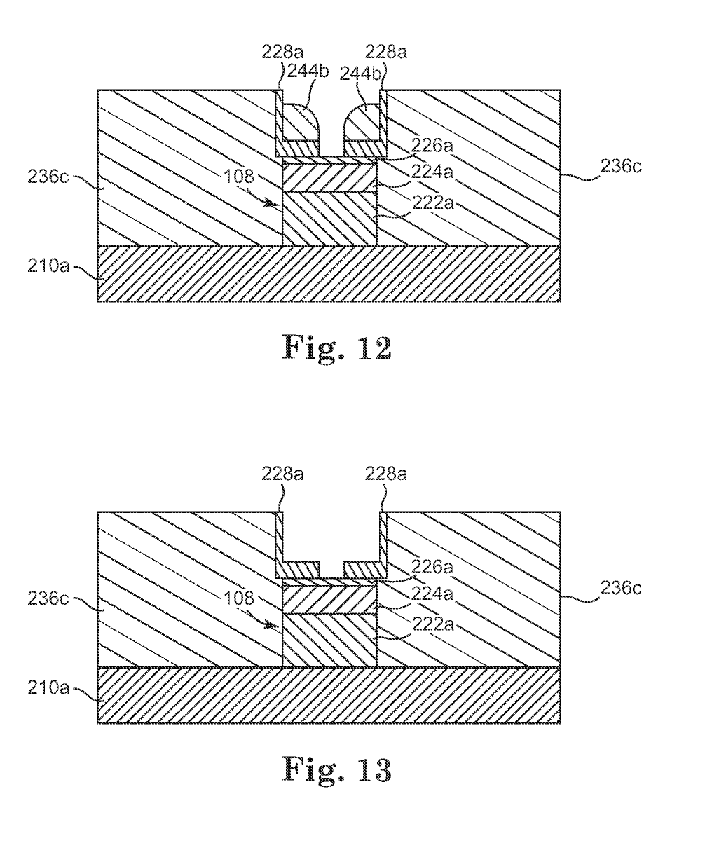

FIG. 12 illustrates a cross-sectional view of one embodiment of first word line 210a, diode 108, silicide contact 226a, first dielectric material layer 236c, dielectric material 228a, and the layer 244b after etching third dielectric material layer 221b. Third dielectric material layer 221b is etched to expose first dielectric material layer 236c and a portion of silicide contact 226a to provide dielectric material 228a.

FIG. 13 illustrates a cross-sectional view of one embodiment of first word line 210a, diode 108, silicide contact 226a, first dielectric material layer 236c, and dielectric material 228a after removing the layer 244b. The layer 244b is etched to expose dielectric material 228a.

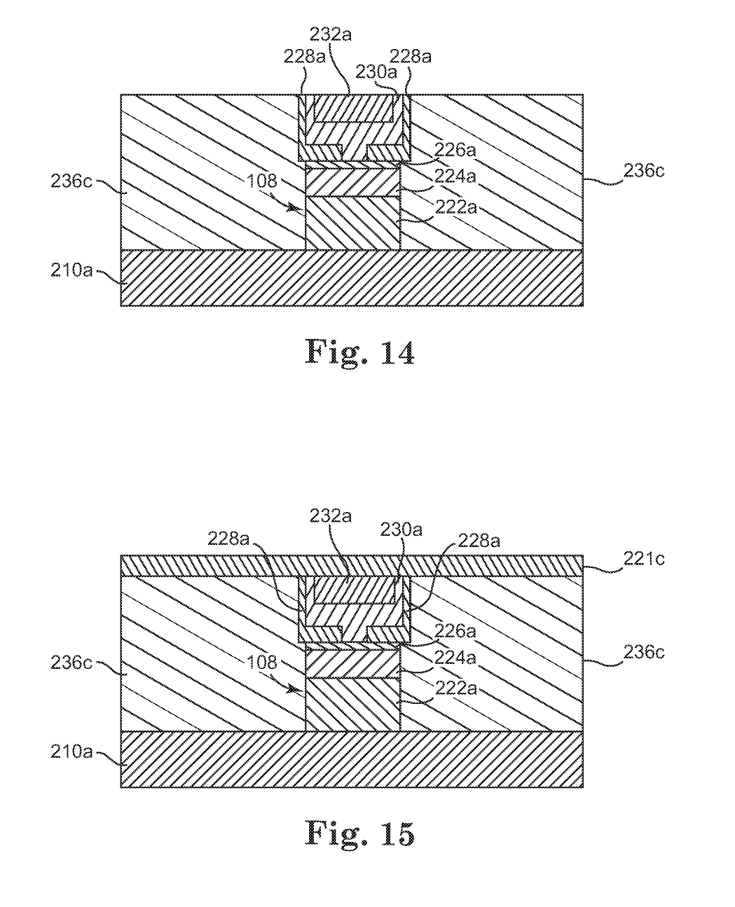

FIG. 14 illustrates a cross-sectional view of one embodiment of first word line 210a, diode 108, silicide contact 226a, first dielectric material layer 236c, dielectric material 228a, a phase change material storage location 230a, and a top electrode 232a. A phase change material, such as a chalcogenide compound material or another suitable phase change material is deposited over exposed portions of first dielectric material layer 236c, dielectric material 228a, and silicide contact 226a to provide a phase change material layer. The phase change material layer is deposited using CVD, HDP-CVD, ALD, MOCVD, PVD, JVD, or other suitable deposition technique.

An electrode material, such as such as TiN, TaN, W, WN, Al, C, Ti, Ta, TiSiN, TaSiN, TiAlN, TaAlN, Cu, or another suitable electrode material is deposited over the phase change material layer to provide an electrode material layer. The electrode material layer is deposited using CVD, HDP-CVD, ALD, MOCVD, PVD, JVD, or other suitable deposition technique. The electrode material layer and the phase change material layer are then planarized to expose first dielectric material layer 236c and to provide top electrode 232a and phase change material storage location 230a. The electrode material layer and the phase change material layer are planarized using CMP or another suitable planarization technique. In other embodiments, other suitable processes are used to fabricate phase change material storage location 230a and top electrode 232a having other suitable configurations.

FIG. 15 illustrates a cross-sectional view of one embodiment of first word line 210a, diode 108, silicide contact 226a, first dielectric material layer 236c, dielectric material 228a, phase change material storage location 230a, top electrode 232a, and a cap material layer 221c. A dielectric material, such as SiN or another suitable dielectric material is deposited over exposed portions of first dielectric material layer 236c, dielectric material 228a, phase change material storage location 230a, and top electrode 232a to provide cap material layer 221c. Cap material layer 221c is deposited using CVD, HDP-CVD, ALD, MOCVD, PVD, JVD, or other suitable deposition technique.

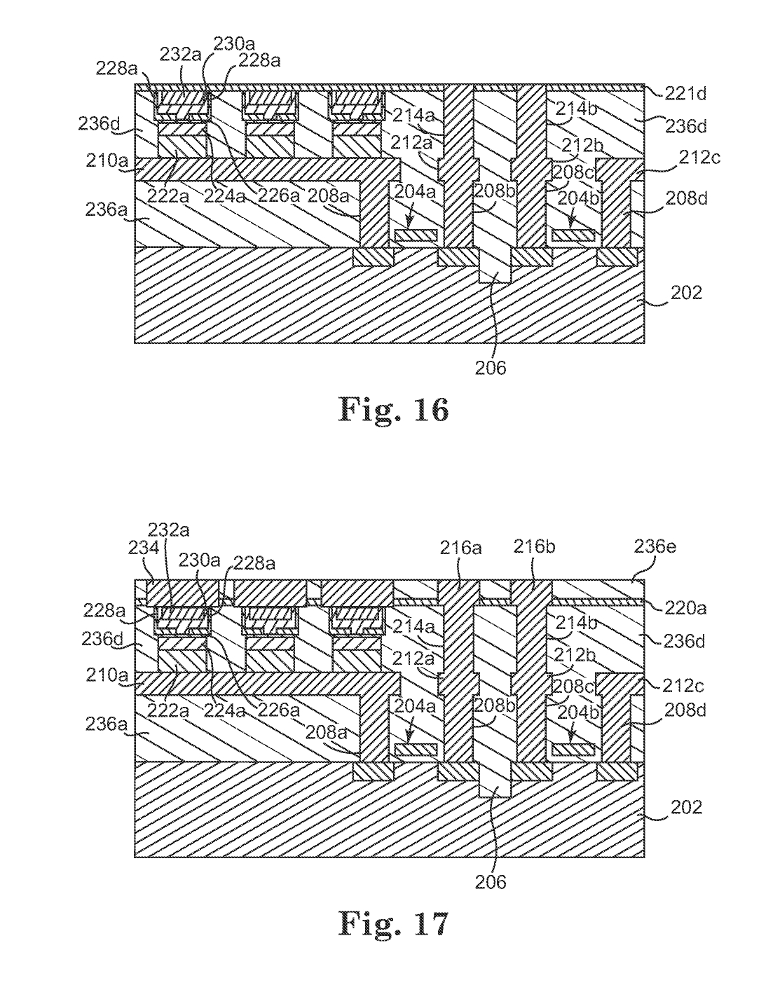

FIG. 16 illustrates a cross-sectional view of one embodiment of the array of diode phase change memory cells after fabricating vias 214a and 214b. Cap material layer 221c and first dielectric material layer 236c are etched to provide openings exposing portions of contacts 212a and 212b and to provide cap material layer 221d and first dielectric material layer 236d. A metal, such as W, Al, Cu, or another suitable metal is deposited over exposed portions of cap material layer 221d, first dielectric material layer 236d, and contacts 212a and 212b to provide a metal layer. The metal layer is deposited using CVD, HDP-CVD, ALD, MOCVD, PVD, JVD, or other suitable deposition technique. The metal layer is then planarized using CMP or another suitable planarization technique to expose cap material layer 221d and to provide vias 214a and 214b.

FIG. 17 illustrates a cross-sectional view of one embodiment of the array of diode phase change memory cells after fabricating bit lines 234 and contacts 216a and 216b. Cap material layer 221d is etched to expose top electrodes 232a, phase change material storage locations 230a, and dielectric material 228a and to provide dielectric material layer 220a. A metal, such as W, Al, Cu, or another suitable metal is deposited over exposed portions of dielectric material layer 220a, vias 214a and 214b, top electrodes 232a, phase change material storage locations 230a, and dielectric material 228a to provide a metal layer. The metal layer is deposited using CVD, HDP-CVD, ALD, MOCVD, PVD, JVD, or other suitable deposition technique. The metal layer is then etched to provide bit lines 234 and contacts 216a and 216b.

A dielectric material, such as SiO₂, SiOₓ, SiN, FSG, BPSG, BSG, or another suitable dielectric material is deposited over exposed portions of bit lines 234, contacts 216a and 216b, and dielectric material layer 220a to provide a dielectric material layer. The dielectric material layer is deposited using CVD, HDP-CVD, ALD, MOCVD, PVD, JVD, or other suitable deposition technique. The dielectric material layer is then planarized to expose bit lines 234 and contacts 216a and 216b and to provide dielectric material 236e.

A process similar to the process previously described and illustrated with reference to FIGS. 5-16 is then repeated to fabricate second diode phase change memory cells 201b of three dimensional array 200a as previously described and illustrated with reference to FIG. 3.

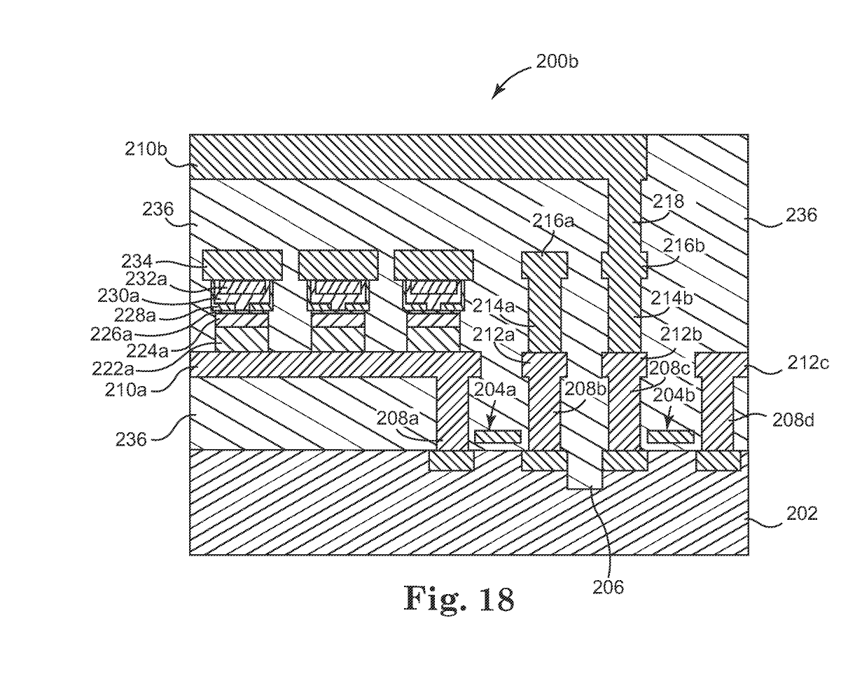

FIG. 18 illustrates a cross-sectional view of another embodiment of an array 200b of diode phase change memory cells. Array 200b is similar to three dimensional array 200a previously described and illustrated with reference to FIG. 3 except that array 200b includes only a single two dimensional array of diode phase change memory cells. In array 200b, diode phase change memory cells 201b are excluded. Array 200b is fabricated similarly to three dimensional array 200a.

Embodiments provide two dimensional and three dimensional arrays of diode phase change memory cells. The diode phase change memory cells are accessed through metal word lines and metal bit lines. The arrays of diode phase change memory cells provide increased memory density and small memory cell size compared to typical diode memory cells.

While the specific embodiments described herein substantially focused on using phase change memory elements, the present invention can be applied to any suitable type of resistive or resistivity changing memory elements.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a first metal line;
a first diode coupled to the first metal line;
first resistivity changing material coupled to the first diode; and
a second metal line coupled to the first resistivity changing material.

2. The integrated circuit of claim 1, further comprising:
a second diode coupled to the second metal line;
second resistivity changing material coupled to the second diode; and
a third metal line coupled to the second resistivity changing material,
wherein the second diode and the second resistivity changing material are above the first diode and the first resistivity changing material.

3. The integrated circuit of claim 2, further comprising:
at least one additional memory cell layer comprising:
a fourth metal line above the third metal line;
a third diode coupled to the fourth metal line;
third resistivity changing material coupled to the third diode; and
a fifth metal line coupled to the third resistivity changing material.

4. The integrated circuit of claim 1, further comprising:
a silicide contact coupled between the first diode and the first resistivity changing material; and
an electrode coupled between the first resistivity changing material and the second metal line.

5. The integrated circuit of claim 4, further comprising:
a dielectric material contacting the first resistivity changing material and the silicide contact, the dielectric material defining an interface between the first resistivity changing material and the silicide contact.

6. The integrated circuit of claim 5, wherein the interface has a sublithographic cross-section.

7. The integrated circuit of claim 1, wherein the first resistivity changing material comprises a phase change material.

8. A system comprising:
a host; and
a memory device communicatively coupled to the host, the memory device comprising:
a first metal word line;
a first vertical diode coupled to the first metal word line;
a first resistive memory element coupled to the first vertical diode; and
a metal bit line coupled to the first resistive memory element.

9. The system of claim 8, wherein the memory device further comprises:
a second vertical diode coupled to the metal bit line;
a second resistive memory element coupled to the second vertical diode; and
a second metal word line coupled to the second resistive memory element.
wherein the second metal word line is aligned above the first metal word line.

10. The system of claim 9, wherein the first and second word lines are perpendicular to the bit line.

11. The system of claim 9, wherein the memory device further comprises:
a write circuit configured to program the first and second resistive memory elements to a selected resistance state;
a sense circuit configured to read a resistance state of the first and second resistive memory elements; and
a controller configured to control the write circuit and the sense circuit.

12. The system of claim 8, wherein the first resistive memory element comprises a phase change element.

13. A memory comprising:
a first word line;
a first diode phase change memory cell coupled to the first word line;
a bit line coupled to the first diode phase change memory cell;
a second diode phase change memory cell coupled to the bit line; and
a second word line coupled to the second diode phase change memory cell,
wherein the second diode phase change memory cell is above the first diode phase change memory cell.

14. The memory of claim 13, wherein the first diode phase change memory cell comprises a first diode coupled to the first word line and a first phase change element coupled between the first diode and the bit line, and
wherein the second diode phase change memory cell comprises a second diode coupled to the bit line and a second phase change element coupled between the second diode and the second word line.

15. The memory of claim 14, wherein each of the first phase change element and the second phase change element comprise an active phase change region having a sublithographic cross-section.

16. The memory of claim 13, further comprising:
first means for selecting the first word line; and
second means for selecting the second word line.

17. The memory of claim 13, wherein the first word line comprises a first metal word line,
wherein the bit line comprises a metal bit line, and
wherein the second word line comprises a second metal word line.

18. A method for fabricating an integrated circuit, the method comprising:
fabricating a first metal line;
fabricating a first vertical diode coupled to the first metal line;
fabricating a first resistivity changing material element coupled to the first vertical diode; and
fabricating a second metal line coupled to the first resistivity changing material element.

19. The method of claim 18, further comprising:
fabricating a second vertical diode coupled to the second metal line;
fabricating a second resistivity changing material element coupled to the second vertical diode; and
fabricating a third metal line coupled to the second resistivity changing material element.

20. The method of claim 18, wherein fabricating the first vertical diode comprises:
depositing a first dielectric material layer over the first metal line;
depositing a second dielectric material layer over the first dielectric material layer;
etching an opening in the first and second dielectric material layers to expose a portion of the first metal line;
filling the opening with silicon;
etching back the silicon to expose a portion of sidewalls of the opening; and
implanting the silicon to form doped regions to provide the first vertical diode.

21. The method of claim 20, wherein fabricating the first resistivity changing material element comprises:
forming a silicide contact over the first vertical diode;
selectively etching the first dielectric material layer to provide an overhang of the second dielectric material layer;
depositing a third dielectric material layer over exposed portions of the silicide contact and the first and second dielectric material layers;
conformally depositing a conformal layer over the third dielectric material layer to form a keyhole in the opening;
spacer etching the conformal layer to expose a portion of the third dielectric material layer above the silicide contact;
etching the exposed portion of the third dielectric material layer to expose a portion of the silicide contact;
removing the etched conformal layer;
depositing resistivity changing material over the exposed portion of the silicide contact; and
depositing an electrode material over the resistivity changing material.

22. A method for fabricating a memory, the method comprising:
fabricating a first word line;
fabricating a first vertical diode coupled to the first word line;
fabricating a first phase change element coupled to the first vertical diode;
fabricating a first bit line coupled to the first phase change element;
fabricating a second vertical diode coupled to the first bit line;
fabricating a second phase change element coupled to the second vertical diode; and
fabricating a second word line coupled to the second phase change element.

23. The method of claim 22, wherein fabricating the first word line comprises fabricating a first metal word line,
wherein fabricating the first bit line comprises fabricating a first metal bit line, and
wherein fabricating the second word line comprises fabricating a second metal word line.

24. The method of claim 22, further comprising:
fabricating at least one additional memory cell layer comprising:
fabricating a third word line above the second word line;
fabricating a third vertical diode coupled to the third word line;
fabricating a third phase change element coupled to the third vertical diode; and
fabricating a second bit line coupled to the third phase change element.

25. The method of claim 22, wherein fabricating the first phase change element comprises fabricating a first phase change element including an active phase change region having a sublithographic cross-section.
